(19) United States
(12) Patent Application Publication
(10) Pub. No.: US 2007/0120191 A1
(43) Pub. Date: May 31, 2007

(54) High trigger current electrostatic discharge protection device

(75) Inventor: David Litfin, Houlton, WI (US)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: Polar Semiconductor, Inc., Bloomington, MN (US)

(21) Appl. No.: 11/287,646

(22) Filed: Nov. 28, 2005

(51) Int. Cl. H01L 23/62

(52) U.S. Cl. 257/355

(57) ABSTRACT

An electrostatic discharge protection device with a high trigger current includes a semiconductor layer, a well region formed in the semiconductor layer, an anode region formed in the well region, a cathode region formed in the semiconductor layer, a bridging region bridging a junction between the semiconductor layer and the well region, and a heavily doped P-region encircling the cathode region.

### BACKGROUND OF THE INVENTION

The invention relates generally to electrostatic discharge (ESD) protection devices. More particularly, it relates to ESD protection devices used with integrated circuits.

Integrated circuits are vulnerable to damage from electrostatic discharge (ESD) from a charged body, such as a human being, that physically contacts the integrated circuit. Transient voltages caused by the ESD may exceed the integrated circuit's capacity to conduct. ESD protection devices are typically placed at each external terminal of the integrated circuit, where they can intercept the transient voltage spikes caused by ESD.

Essentially, an ESD protection device is a switch that is turned on by a transient voltage spike, and which provides a safe discharge path for the current associated with the transient voltage spike. ESD protection devices generally operate by providing a very high resistance (essentially an open circuit) during normal operation of the integrated circuit. However, if an electrostatic discharge creates a large spike in voltage, the ESD protection device turns on and provides a very low resistance path that shunts excess current away from the portion of the integrated circuit that may be damaged by the voltage spike, thereby protecting the integrated circuit.

A variant of a silicon controlled rectifier (SCR), a thyristor, is a commonly used ESD protection device. Thyristors are semiconductor devices that consist of a PNPN or NPNP series of layers. Thyristors can be switched between a high impedance/low current OFF state and a low impedance/high current ON state.

A thyristor is modeled as two bipolar transistors: a PNP transistor and an NPN transistor in which the base of the PNP transistor is connected to the collector of the NPN transistor and the collector of the PNP transistor is connected to the base of the NPN transistor. The PNP emitter acts as the anode of the thyristor and the NPN emitter acts as the cathode. A voltage is applied to the anode and the cathode is held to ground. During normal operation, both transistors are reversed biased and therefore in cut-off. When a voltage spike occurs at the anode, it forward biases the emitter-base junction of the PNP transistor, and the PNP transistor turns on. The current through the PNP transistor flows into its collector, which is also the base of the NPN transistor. As a result, the emitter-base junction of the NPN transistor becomes forward biased, and it also turns on. Current flows from the collector of the NPN transistor to the emitter of the NPN transistor, which is also the base of the PNP transistor. This forward-biases the PNP transistor, so that the voltage at the emitter of the PNP transistor (i.e., the voltage spike) is no longer needed to provide the bias for the PNP transistor to stay turned on.

Two important parameters for the thyristor are the trigger voltage (V_{trig}) and the trigger current (I_{trig}). The trigger voltage is the amount of voltage that is required to forward bias the emitter-base junction of the PNP transistor. The trigger current is the amount of current that is needed to forward bias the emitter-base junction of the PNP transistor. That is, the PNP transistor will not be forward biased, and the thyristor will not turn on, unless the transient voltage spike has a voltage of at least the trigger voltage and a current of at least the trigger current.

When used as an ESD protection circuit, the thyristor is connected as a two terminal device, with the emitter and base of the PNP transistor tied together and the emitter and base of the NPN transistor tied together. Triggering requires avalanche breakdown of a PN junction. The thyristor turns on either when the emitter of the NPN transistor is forward biased by the hole current in its P region base or when the PNP transistor is turned on by the electron current in its N region base. Typically, the NPN transistor gain is an order of magnitude higher than the PNP transistor gain at low current levels, so turning on the NPN transistor is easier than turning on the PNP transistor.

In designing ESD protection devices, it is preferred that the device can be implemented using standard fabrication techniques. Furthermore, the ESD protection device should take up little room on the integrated circuit, avoid latch-up under normal operating conditions, and it should operate at an appropriate current. If the ESD protection device is triggered at a low current, there is a danger that the device will be activated by small transient currents, thereby interfering with the normal operation of the integrated circuit. Accidental triggering of an ESD protection device may also cause a catastrophic latch-up event.

Accidental triggering of an ESD protection device can interfere with the normal operation of an integrated circuit. In an extreme case, it can cause catastrophic latch-up and destroy the chip. One way to prevent accidental triggering of an ESD protection device is to increase the trigger current of the device. Thus, there is a need for a thyristor with a higher trigger current than conventional thyristors, so that the problem of accidental triggering may be overcome.

### SUMMARY OF THE INVENTION

An electrostatic discharge protection device with a high trigger current includes a semiconductor layer, a well region formed in the semiconductor layer, an anode region formed in the well region, a cathode region formed in the semiconductor layer, a bridging region bridging a junction between the semiconductor layer and the well region, and a channel stop region encircling the cathode region.

### DESCRIPTION OF THE DRAWINGS

FIG. 1 is a cross-sectional view of an ESD protective device according to one embodiment of the invention.

FIG. 2 is a current-voltage (IV) graph showing the current-voltage relationship of the invention and comparing it to conventional ESD protection devices.

While the above-identified drawing figures set forth embodiments of the invention, other embodiments are also contemplated, as noted in the discussion. In all cases, this disclosure presents the invention by way of representation, and not limitation. It should be understood that numerous other modifications and embodiments that fall within the scope and spirit of the principals of this invention can be devised by those skilled in the art. The figures may not be drawn to scale.

### DETAILED DESCRIPTION

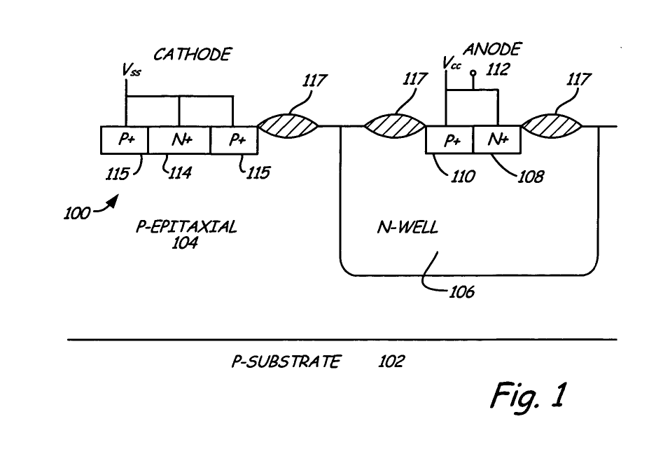

FIG. 1 shows an implementation of the present invention. ESD protection device 100 is built upon P-type semiconductor substrate 102. P-epitaxial layer 104 is grown on P-substrate 102 forming a P-type region, and N-well 106 is located in P-epitaxial layer 104. On the surface of the circuit, heavily doped N-region 108 and heavily doped P-region 110 are located in N-well 106. Heavily doped P-region 110 is connected to supply voltage V_{cc} and functions as the anode of the ESD protection device. Both heavily doped N-region 108 and heavily doped P-region 110 are connected to input 112. Heavily doped N-region 116 bridges N-well 106 and P-epitaxial region 104. Heavily doped N-region 114 is located in P-epitaxial layer 104 and functions as the cathode of the device. Heavily doped P-region 115 surrounds heavily doped N-region 114. Because FIG. 1 is a cross-sectional view, heavily doped P-region 115 appears as two separate areas; however, it is actually a ring that encircles the cathode. A field oxide 117 separates the components at the surface.

In operation, ESD protection device 100 works as two transistors. A PNP transistor is formed by heavily doped P-region 110 as the emitter; N-well 106 as the base; and P-substrate 102 and P-epitaxial region 104 as the collector. An NPN transistor is formed by heavily doped N-layer 114 as the emitter; channel stop region 118 and P-epitaxial region 104 as the base; and heavily doped N-region 116, N-well 106 and heavily doped N-region 108 as collector. The PNP emitter (heavily doped P-region 110) acts as the anode of ESD protection device 100 and the NPN emitter (heavily doped N-region 114) acts as the cathode.

ESD protection device 100 has a significantly higher trigger current than conventional ESD protection devices, because heavily doped P-region 115 siphons majority carriers (i.e., holes) from P-epitaxial region 104. In order for ESD protection device 100 to become activated, the base-emitter junction of the NPN transistor, which is the junction between heavily-doped N region 114 and P-epitaxial region 104, must become forward biased. Since heavily doped P-region 115 siphons holes from P-epitaxial region 104 a higher current is necessary in order to forward bias the base-emitter junction of the NPN transistor. Thus, a higher trigger current is needed to activate ESD protection device 100.

One skilled in the art will recognize that the embodiment of the invention shown in FIG. 1 is an example that shows the relationship between positively and negatively doped regions in ESD protection device 100, and the invention is not limited to the exact structure shown. Design of microelectronic structures is a complex process that necessarily involves many decisions and many trade-offs. Doped regions may be created in different ways, such as by diffusion or epitaxial growth, without changing the basic nature in which they function. Thus, for example, p-epitaxial region 104 might, in practice, be a p-tub region that is diffused into an n-tub region, without changing the nature in which the invention functions. Also, positively and negatively doped regions could be reversed.

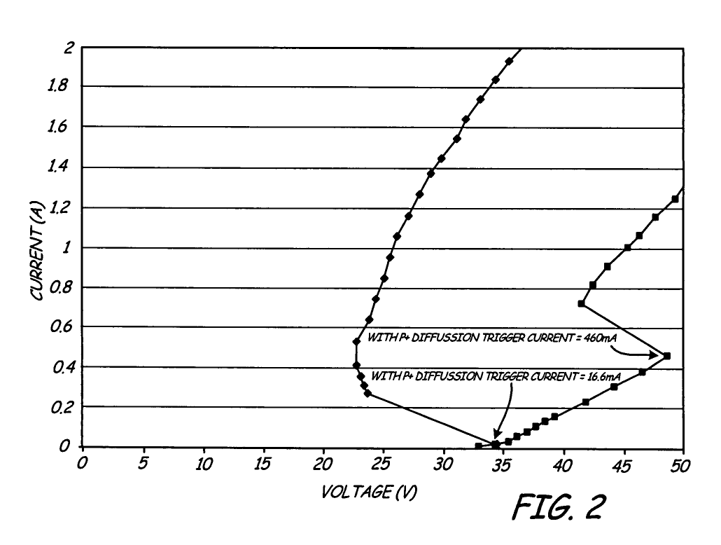

FIG. 2 is a current-voltage (IV) curve showing the relationship between current and voltage in ESD protection device 100 and comparing it to the current voltage relationship in a conventional ESD protection device. A conventional ESD protection device has a trigger current of 16.6 milliamps (mA). ESD protection device 100, however, has a trigger current of more than 450 mA. Thus, adding a heavily doped P-region that encircles the cathode results in raising the trigger current by more than an order of magnitude. The measurements shown in FIG. 2 were measured using the standard ESD device testing method of Transmission Line Pulsing.

The invention is an ESD protection device with a relatively higher trigger current than conventional ESD protection devices. The invention uses a ring of heavily-doped P-type material to encircle the emitter of the NPN transistor. This heavily doped P-region siphons holes from the base region of the NPN transistor, reducing the bias of the base-emitter junction and making it harder for the NPN transistor to turn on. As a result, a higher current is needed to overcome the siphoning effect of the channel stop region and turn on the transistor. Because a higher current is needed before the ESD protection device is trigger, accidental triggering of the ESD protection device is avoided. This reduces the chance of catastrophic latch-up that could destroy the chip.

Although the present invention has been described with reference to preferred embodiments, workers skilled in the art will recognize that changes may be made in form and detail without departing from the spirit and scope of the invention.

1. An electrostatic discharge protection device comprising:
a first semiconductor layer of a first conductivity type;
a first semiconductor region of a second conductivity type formed in the first semiconductor layer;
a first highly doped semiconductor region of the first conductivity type formed in the first semiconductor region of the second conductivity type;
a first highly doped semiconductor region of the second conductivity type formed in the first semiconductor region of the first conductivity type;
a second highly doped region of the second conductivity type formed in both the first semiconductor layer of the first conductivity type and the first semiconductor region of the second conductivity type and bridging a junction between the first semiconductor layer of the first conductivity type and the first semiconductor region of the second conductivity type; and
a second highly doped region of the first conductivity type formed in the first semiconductor layer of the first conductivity type and encircling the first highly doped semiconductor region of the second conductivity type.

2. The electrostatic discharge protection device of claim 1 wherein the first conductivity type is p-type and the second conductivity type is n-type.

3. The electrostatic discharge protection device of claim 1 wherein the first conductivity type is n-type and the second conductivity type is p-type.

4. The electrostatic discharge protection device of claim 1 wherein the device is formed on an integrated circuit.

5. The electrostatic discharge protection device of claim 1 wherein the ESD protection device has a trigger current and the trigger current is more than 450 milliamps.

6. An electrostatic discharge protection device comprising:
a semiconductor layer of a first conductivity type;
a well region of a second conductivity type formed in the semiconductor layer;
an anode region of a first conductivity type formed in the well region;
a cathode region of a second conductivity type formed in the semiconductor layer;
a bridging region of a second conductivity type formed in both the semiconductor layer and the well region and bridging a junction between the semiconductor layer and the well region; and
a region of a first conductivity type formed in the semiconductor layer and encircling the cathode region.

7. The electrostatic discharge protection device of claim 6 wherein the first conductivity type is p-type and the second conductivity type is n-type.

8. The electrostatic discharge protection device of claim 6 wherein the first conductivity type is n-type and the second conductivity type is p-type.

9. The electrostatic discharge protection device of claim 6 wherein the device is formed on an integrated circuit.

10. The electrostatic discharge protection device of claim 6 wherein the ESD protection device has a trigger current and the trigger current is more than 450 milliamps.

11. An electrostatic discharge protection device protection device comprising:
a n region formed in a p region;
a first p+ region formed in the n region and defining an anode;
a first n+ region formed in the p region, the first n+ region being laterally spaced from the first p+ region and defining a cathode;
a second n+ region formed in both the n region and the p region and laterally spaced from both the first p+ region and the first n+ region;
a second p+ region formed in the p material, the second p+ region encircling the cathode.

12. The electrostatic discharge protection device of claim 11 wherein the device is formed on an integrated circuit.

13. The electrostatic discharge protection device of claim 11 wherein the ESD protection device has a trigger current and the trigger current is more than 450 milliamps.
